(19) United States
(12) Patent Application Publication
(10) Pub. No.: US 2026/0260051 A1
(43) Pub. Date: Sep. 3, 2026

(54) AUTOMATED ROUTING SYSTEM AND AUTOMATED ROUTING METHOD THEREOF

(71) Applicant: Inventec Corporation, Taipei (TW)

(72) Inventors: Ying-Sheng Luo, Taipei (TW); Guilherme Henrique Galelli Christmann, Taipei (TW); Yan-Yue Yin, Taipei (TW); Chen-Chou Huang, Taipei (TW); Chiu-Jung Lu, Taipei (TW); Wei-Chao Chen, Taipei (TW)

(73) Assignee: Inventec Corporation, Taipei (TW)

(21) Appl. No.: 19/326,698

(22) Filed: Sep. 11, 2025

(30) Foreign Application Priority Data
Feb. 28, 2025 (CN) 202510229735.X

(51) Int. Cl. G06F 30/394; G06F 30/3308

(52) U.S. Cl. CPC G06F 30/394; G06F 30/3308

(57) ABSTRACT

An automated routing system and an automated routing method thereof are provided. The automated routing system has a processor and a memory device. The memory device is coupled to the processor and stores a program and design information. The design information includes a start point, an end point, a first direction, and a second direction. The processor executes the program to generate a simulated trace from the start point to the end point. An initial segment of the simulated trace is connected to the start point and extends from the start point towards the first direction, and an end segment of the simulated trace is connected to the end point and extends from the end point towards the second direction.

### BACKGROUND OF THE INVENTION

### 1. Field of the Invention

The present invention relates to an automated routing system and an automated routing method thereof, and more particularly, to an automated routing system and an automated routing method that consider the routing directionality of a start point and an end point.

### 2. Description of the Prior Art

An automated routing system is an intelligent technology capable of automatically generating interconnects between various components in an electronic circuit design. This system, based on a circuit diagram, utilizes advanced algorithms to automatically calculate and generate optimal connection paths. This technology not only greatly reduces the workload of engineers performing manual routing, improving design efficiency, but also significantly lowers the incidence of design errors.

Traditional automated routing systems, when generating routing paths, typically primarily consider factors such as trace length and trace width to obtain an optimal routing solution. However, this method often overlooks the directionality of the traces. In practical applications, many electronic components, especially connectors, have specific access direction requirements. If the automatically generated routing paths do not conform to these directions, it may lead to unachievable routing, or require additional modifications or even re-routing, which undoubtedly increases design cost and time.

### SUMMARY OF THE INVENTION

An embodiment of the present invention discloses an automated routing method, which comprises setting a start point and an end point. executing a program by a processor to set a first direction and a second direction; and executing the program by the processor to generate a simulated trace from the start point to the end point. Wherein, a starting segment of the simulated trace is connected to the start point and extends from the start point toward the first direction, and an ending segment of the simulated trace is connected to the end point and extends from the end point toward the second direction.

An embodiment of the present invention discloses an automated routing system, which comprises a processor and a memory device. The memory device is coupled to the processor and stores a program and design information. The design information includes a start point, an end point, a first direction, and a second direction. The processor executes the program to generate a simulated trace from the start point to the end point. A starting segment of the simulated trace is connected to the start point and extends from the start point toward the first direction, and an ending segment of the simulated trace is connected to the end point and extends from the end point toward the second direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of an automated routing system according to an embodiment of the present invention.

FIG. 2 is a schematic diagram of a simulated trace generated by the automated routing system of FIG. 1.

FIG. 3 is a schematic diagram of another simulated trace generated by the automated routing system of FIG. 1.

FIG. 4 is a schematic diagram of another simulated trace generated by the automated routing system of FIG. 1.

FIG. 5 is a flowchart of an automated routing method according to an embodiment of the present invention.

### DETAILED DESCRIPTION

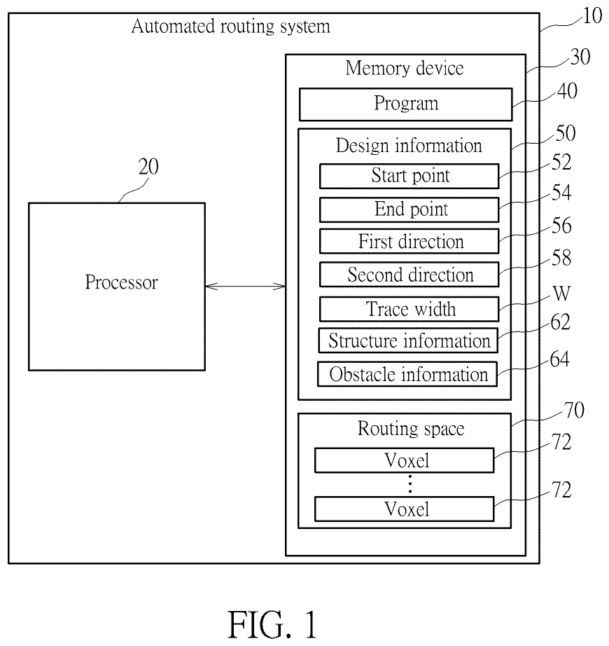

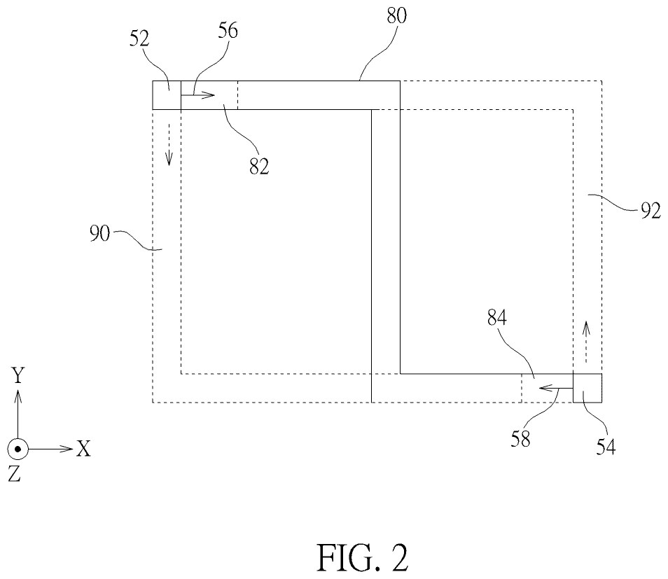

FIG. 1 is a functional block diagram of an automated routing system 10 according to an embodiment of the present invention. FIG. 2 is a schematic diagram of a simulated trace 80 generated by the automated routing system 10 of FIG. 1. The automated routing system 10 efficiently and accurately generates the simulated trace that meets design requirements, for application in fields such as printed circuit board (PCB) design and integrated circuit layout. The automated routing system 10 includes a processor 20 and a memory device 30. The memory device 30 is coupled to the processor 20 and stores all necessary data for the operation of the automated routing system 10, these necessary data including a program 40 and design information 50. The processor 20 serves as a core of the system, responsible for executing the program 40 to perform routing algorithm computations and generating the simulated trace 80 based on the design information 50. The program 40 may include, but is not limited to, routing algorithms and data structures. The design information 50 may include, but is not limited to, a start point 52, an end point 54, a first direction 56, and a second direction 58. The design information 50 may also include other design constraints, such as: a trace width W, structure information 62, obstacle information 64, turn count, waypoints, layer count, spacing, keep-out areas, etc., to ensure that the simulated trace 80 complies with design rules.

The memory device 30 may be a random access memory (RAM) or a non-volatile memory. The random access memory may be a dynamic random access memory (DRAM) or a static random access memory (SRAM), and the non-volatile memory may be a flash memory, a programmable read-only memory (PROM), an erasable programmable read-only memory (EPROM), or an electrically erasable programmable read-only memory (EEPROM), etc.

In this embodiment, the processor 20 executes the program 40 to generate the simulated trace 80 from the start point 52 to the end point 54. A starting segment 82 of the simulated trace 80 is connected to the start point 52 and extends from the start point 52 toward the first direction 56, while an ending segment 84 of the simulated trace 80 is connected to the end point 54 and extends from the end point 54 toward the second direction 58. Therefore, the automated routing system 10 can ensure that the generated simulated trace 80 strictly adheres to the first direction 56 and the second direction 58. This strict control over trace directionality enables the simulated trace 80 generated by the automated routing system 10 to perfectly match the directions of connectors respectively located at the start point 52 and the end point 54. To more intuitively illustrate the advantages of the automated routing system 10, in addition to the simulated trace 80 that meets design requirements, FIG. 2 also shows two traces 90 and 92 that do not meet the design requirements. A first direction of the trace 90 is in the opposite direction of a Y-axis and is inconsistent with the first direction 56, while a second direction of the trace 92 is in the same direction as the Y-axis and is inconsistent with the second direction 58. Both of these situations violate design specifications, causing the traces 90 and 92 not to meet the requirements for the first direction 56 and the second direction 58. However, through the program 40 executed by the processor 20, the automated routing system 10 automatically excludes these non-compliant traces 90 and 92. The automated routing system 10 evaluates all possible traces based on the first direction 56 and the second direction 58 in the design information 50, and selects those traces that strictly adhere to the directional constraints. This automated filtering process ensures that the finally generated simulated trace 80 meets the design requirements.

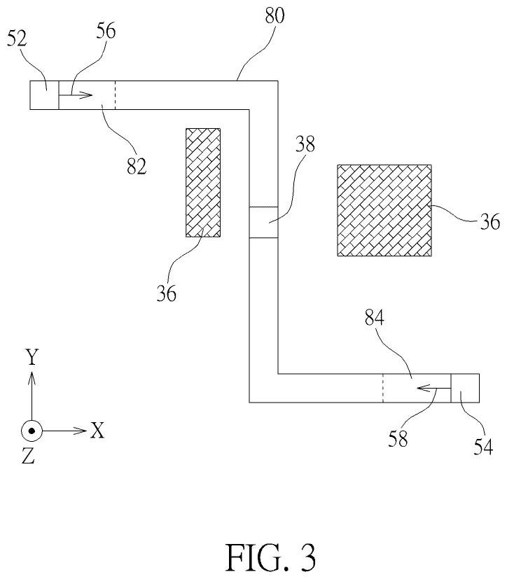

FIG. 3 is a schematic diagram of another simulated trace 80 generated by the automated routing system 10 of FIG. 1, according to another embodiment of the present invention. This embodiment further considers obstacles that may be encountered during the routing process, thereby improving routing flexibility and reliability. In this embodiment, the design information 50, in addition to including the start point 52, the end point 54, the first direction 56, and the second direction 58, also additionally includes obstacle information 64 of at least an obstacle 36. The obstacle information 64 of the obstacle(s) 36 describes in detail information such as the position and size of all obstacles in a routing space, and this information can be in various forms, for example: coordinates (e.g., coordinates of four vertices of the obstacle(s) 36), dimensions (e.g., length and width of the obstacle), and a shape of the obstacle(s) 36 (e.g., rectangle, circle, etc.). The program 40 executed by the processor 20 will fully utilize the obstacle information 64 of the obstacle(s) 36 and, when generating the simulated trace 80, strictly prevent the simulated trace 80 from overlapping with any obstacle 36. The program 40 will employ an efficient collision detection algorithm to inspect each generated trace segment, ensuring that the simulated trace 80 does not intersect with any obstacle 36, thereby causing the simulated trace 80 to route around the obstacle(s) 36. By considering the obstacle(s) 36, the automated routing system 10 is able to find feasible traces in complex routing environments, increasing the routing success rate. Furthermore, by preventing the simulated trace 80 from overlapping with the obstacle(s) 36, the automated routing system 10 can reduce routing errors and improve product reliability.

In an embodiment of the present invention, the design information 50 further includes information of a waypoint 38. The information of the waypoint 38 includes a coordinate position of the waypoint 38 in the routing space. The program 40 executed by the processor 20 will, based on the information of the waypoint 38 in the design information 50, force the simulated trace 80 to pass through the waypoint 38. Although this embodiment is described with one waypoint 38, the design information 50 may include information of a plurality of waypoints 38, causing the simulated trace 80 to pass through these waypoints 38. Through the introduced waypoint(s) 38, designers can achieve finer control over the routing path, enhancing routing flexibility. Additionally, in certain specific application scenarios, it may be necessary for the simulated trace 80 to pass through certain specific points, and the function of the waypoint(s) 38 can meet these needs.

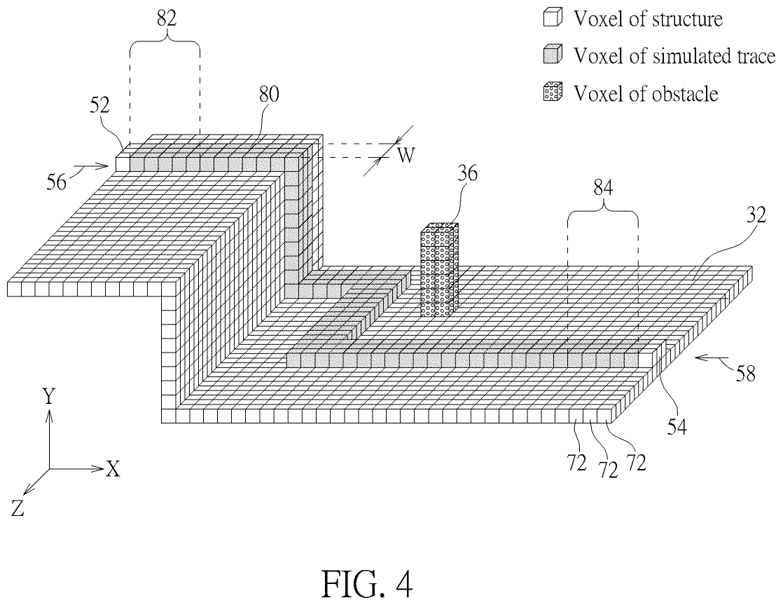

FIG. 4 is a schematic diagram of another simulated trace 80 generated by the automated routing system 10 of FIG. 1, according to another embodiment of the present invention. In this embodiment, the processor 20, by executing the program 40, establishes a routing space 70 using a plurality of voxels 72, and a direction of this routing space 70 can be represented by an X-axis, a Y-axis, and a Z-axis. Each of the voxels 72 may, for example, be a cube with a length, width, and height all of 1 millimeter, but the present invention is not limited thereto. Furthermore, a size of the voxels 72 is not fixed; the automated routing system 10 can adjust the size of the voxels 72 according to design requirements. For example, in a high-density routing area, the automated routing system 10 can use smaller voxels 72 to improve routing accuracy. During the process of generating the simulated trace 80, the program 40 executed by the processor 20 will constrain the start point 52, the end point 54, and the simulated trace 80 to be within the aforementioned routing space 70. Furthermore, in this embodiment, the program 40 executed by the processor 20 will also cause the generated simulated trace 80 to comply with the specifications in the design information 50 regarding the start point 52, the end point 54, the first direction 56, and the second direction 58, i.e., the starting segment 82 of the simulated trace 80 is connected to the start point 52 and extends from the start point 52 toward the first direction 56, and the ending segment 84 of the simulated trace 80 is connected to the end point 54 and extends from the end point 54 toward the second direction 58. Such a design not only enhances routing accuracy but also ensures that the directionality of the simulated trace 80 fully conforms to design specifications, avoiding the issue of inconsistent directionality found in traditional automated routing systems, thereby improving the reliability and accuracy of the overall design.

In an embodiment of the present invention, the design information 50, in addition to including the start point 52, the end point 54, the first direction 56, and the second direction 58, also further includes the trace width W. The program 40 executed by the processor 20 generates the simulated trace 80 according to the trace width W. Specifically, the program 40, based on the trace width W, calculates a number of the voxels 72 occupied by the simulated trace 80 in the routing space 70, and ensures that the voxels 72 occupied by the simulated trace 80 do not conflict with other components or traces, and ensures that the width of the simulated trace 80 remains consistent to meet design requirements. By strictly controlling the trace width W of the simulated trace 80, the automated routing system 10 can improve routing accuracy, reduce routing errors, and improve signal integrity through reasonable trace width design, thereby reducing signal attenuation.

In an embodiment of the present invention, by the processor 20 executing the program 40, the automated routing system 10 is capable of using the voxels 72 occupied by a structure 32 of a circuit board and/or a chassis within the routing space 70 as structure information 62 of the structure 32, and recording the structure information 62 of the structure 32 in the memory device 30. Subsequently, the program 40 executed by the processor 20 generates the simulated trace 80 immediately adjacent to the structure 32 based on the structure information 62 of the structure 32. Specifically, during the process of generating the simulated trace 80, the automated routing system 10 can directly determine whether the voxels 72 occupied by the simulated trace 80 are adjacent to the voxels 72 occupied by the structure 32. This method effectively avoids the situation where the simulated trace 80 is suspended due to not being immediately adjacent to the structure 32, ensuring that the simulated trace 80 maintains close adherence to the structure 32, thereby enhancing the stability and reliability of the trace. Therefore, the automated routing system 10 can, by accurately recording and determining the voxels 72 occupied by the structure 32, and based on these voxels 72, generate the simulated trace 80 immediately adjacent to the structure 32. This not only significantly improves routing accuracy but also effectively reduces design problems that may arise from suspended traces, thereby enhancing the efficiency and quality of the overall design.

In an embodiment of the present invention, the automated routing system 10 meticulously records the voxels 72 occupied by all obstacles 36 within the routing space 70 and stores this information in the memory device 30. When the processor 20 executes the program 40, it first reads the relevant information of these obstacles 36 from the memory device 30 and performs layout planning for the simulated trace 80 according to the limitation of the trace width W. By continuously comparing the voxels 72 occupied by the simulated trace 80 with the voxels 72 occupied by the obstacles 36, the program 40 can effectively cause the simulated trace 80 to route around the obstacles 36, ensuring routing integrity. Such a design accurately records the position of each obstacle 36 in the routing space 70, enabling the program 40 to flexibly bypass these obstacles 36 without affecting the layout of other components. Concurrently, the automated routing system 10 can also find an optimal routing path according to design requirements, which not only effectively reduces the incidence of routing errors but also significantly enhances product reliability. Because the automated routing system 10 can accurately identify and record the positions of the obstacles 36, coupled with the program 40 considering these obstacles 36 when planning the simulated trace 80, the entire process becomes more intelligent and efficient. This means that during the routing process, problems of trace overlap or conflict caused by the obstacles 36 can be avoided, thereby improving the stability and reliability of the entire automated routing system 10, and greatly optimizing the design flow and production efficiency of electronic products.

In an embodiment of the present invention, the automated routing system 10, by the processor 20 executing a highly optimized program 40, generates a plurality of candidate simulated traces within the routing space 70. Each candidate simulated trace strictly adheres to design specifications: its starting segment must be connected to the start point 52 and extend along the specified first direction 56, and its ending segment must be connected to the end point 54 and extend along the second direction 58. To ensure routing integrity, all candidate simulated traces cleverly bypass various obstacles 36 within the routing space, including components, vias, and keep-out zones. Such a design allows the simulated trace to extend smoothly and compactly during generation, thereby ensuring trace reliability. Among the numerous candidate simulated traces, to select an optimal solution, the program 40 accurately calculates a turn count for each candidate simulated trace. A lower turn count signifies a smoother trace and a more compact layout, also implying a shorter trace length and lower signal attenuation. Therefore, the program 40 prioritizes selecting the candidate simulated trace with the fewest turns as the final simulated trace 80. In another embodiment of the present invention, the program 40 selects the simulated trace 80 based on a length of each candidate simulated trace. For example, if two candidate simulated traces have the same turn count, the program 40 will select the candidate simulated trace with the shorter trace length as the final simulated trace 80. In this way, not only can the smoothness and compactness of the trace be ensured, but signal attenuation can also be effectively reduced, further enhancing routing quality and reliability. Through this multifaceted optimization strategy, the automated routing system 10 can significantly improve the efficiency and accuracy of routing design, reduce errors during the design process, and enhance the overall performance and reliability of the product.

In an embodiment of the present invention, to meet the requirements of circuit design, the program 40 executed by the processor 20 may use an A* search algorithm, and select the simulated trace 80 through the following evaluation function f(x), incorporating limitations for minimum turn count and that the path should be immediately adjacent to the structure in the function g(x) therein.

f(x)=g(x)+h(x)

Where f(x) represents a total cost of an x node (e.g., the aforementioned waypoint 38), g(x) is a distance from the start point 52 to the x node, h(x) is an estimated distance from the x node to the end point 54, and the program 40 may use a Manhattan distance to calculate this estimated distance. Wherein, the aforementioned function g(x) can be represented by the following function:

g(x)=D(pₛₜₐᵣₜ, x)+wₜᵤᵣₙₛNₜᵤᵣₙₛ(x)+w_{floating}N_{floating}(x)

Where pₛₜₐᵣₜ is the start point 52, D(pₛₜₐᵣₜ, x) is the distance from the start point 52 to the x node, Nₜᵤᵣₙₛ(x) is a turn count on a path from the start point 52 to the x node, N_{floating}(x) is a number of floating nodes on the path from the start point 52 to the x node, wₜᵤᵣₙₛ is a weight controlling turn penalty, w_{floating} is a weight controlling floating penalty, and both wₜᵤᵣₙₛ and w_{floating} are greater than zero. Wherein, the number of floating nodes N_{floating}(x) represents a number of nodes on the candidate simulated trace that are not immediately adjacent to the structure 32. Additionally, the aforementioned function h(x) can be represented by the following function:

h(x)=D(x, p_{end})

Wherein, p_{end} is the end point 54, and D(x, p_{end}) is the distance from node x to the end point 54.

Where p_{end} is the end point 54, D(x, p_{end}) is the distance from the x node to the end point 54.

The program 40 executed by the processor 20 calculates a value of the function f(x) corresponding to each candidate simulated trace, and compares the values of the function f(x) corresponding to the respective candidate simulated traces, to select the candidate simulated trace corresponding to the minimum value of the function f(x) as the final simulated trace 80.

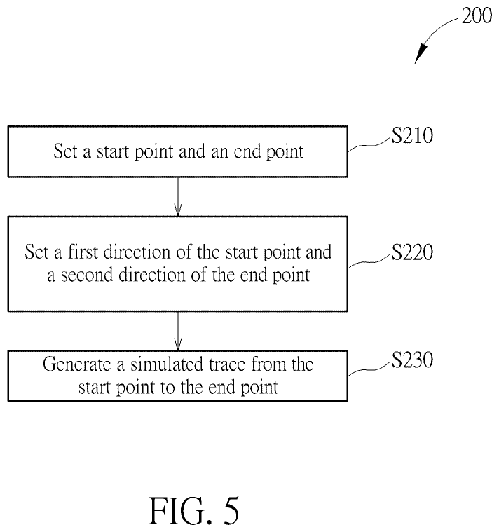

FIG. 5 is a flowchart of an automated routing method 200 according to an embodiment of the present invention. The automated routing system 10 implements the automated routing method 200 by the processor 20 executing the program 40. The automated routing method 200 includes the following steps:
Step S210: Setting the start point 52 and the end point 54, to clearly define coordinate positions of the start point 52 and the end point 54;
Step S220: Setting the first direction 56 and the second direction 58; and
Step S230: Generating the simulated trace 80 from the start point 52 to the end point 54. Wherein, the starting segment 82 of the simulated trace 80 is connected to the start point 52 and extends from the start point 52 toward the first direction 56, and the ending segment 84 of the simulated trace 80 is connected to the end point 54 and extends from the end point 54 toward the second direction 58.

The present invention, by introducing the concept of the first direction of the start point and the second direction of the end point during the routing process, ensures that the generated simulated trace strictly adheres to these directionality requirements. This makes the generated routing path more aligned with actual routing needs, reduces the occurrence of routing errors, and improves routing efficiency and reliability.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An automated routing method, comprising:
executing, by a processor, a program to set a start point and an end point;
executing, by the processor, the program to set a first direction and a second direction; and
executing, by the processor, the program to generate a simulated trace from the start point to the end point, wherein a starting segment of the simulated trace is connected to the start point and extends from the start point toward the first direction, and an ending segment of the simulated trace is connected to the end point and extends from the end point toward the second direction.

2. The automated routing method of claim 1, further comprising:
executing, by the processor, the program to establish a routing space using a plurality of voxels; and
executing, by the processor, the program to constrain the start point, the end point, and the simulated trace to be within the routing space.

3. The automated routing method of claim 2, further comprising:
executing, by the processor, the program to record voxels occupied by a structure within the routing space; and
executing, by the processor, the program to cause the simulated trace to be immediately adjacent to the structure, based on the voxels occupied by the structure within the routing space.

4. The automated routing method of claim 1, wherein the simulated trace is generated according to a trace width.

5. The automated routing method of claim 4, further comprising:
executing, by the processor, the program to record voxels occupied by at least one obstacle within a routing space;
wherein executing, by the processor, the program to generate the simulated trace from the start point to the end point comprises:
executing, by the processor, the program to, according to the trace width, prevent voxels of the simulated trace from overlapping with the voxels occupied by the at least one obstacle within the routing space.

6. The automated routing method of claim 1, further comprising:
executing, by the processor, the program to record a position occupied by at least one obstacle within a routing space; and
executing, by the processor, the program to cause the simulated trace to route around the at least one obstacle.

7. The automated routing method of claim 6, wherein executing, by the processor, the program to generate the simulated trace from the start point to the end point comprises:
executing, by the processor, the program to generate a plurality of candidate simulated traces, wherein each candidate simulated trace routes around the at least one obstacle, a starting segment of each said candidate simulated trace is connected to the start point and extends from the start point toward the first direction, and an ending segment of each said candidate simulated trace is connected to the end point and extends from the end point toward the second direction; and
selecting the simulated trace from the plurality of candidate simulated traces based on a turn count of each candidate simulated trace.

8. The automated routing method of claim 7, wherein the selected simulated trace is one of the plurality of candidate simulated traces having a fewest turn count.

9. The automated routing method of claim 1, further comprising:
executing, by the processor, the program to set at least one waypoint in a routing space; and
executing, by the processor, the program to cause the simulated trace to pass through the at least one waypoint.

10. The automated routing method of claim 1, wherein executing, by the processor, the program to generate the simulated trace from the start point to the end point comprises:
executing, by the processor, the program to generate a plurality of candidate simulated traces, wherein a starting segment of each candidate simulated trace is connected to the start point and extends from the start point toward the first direction, and an ending segment of each said candidate simulated trace is connected to the end point and extends from the end point toward the second direction; and
executing, by the processor, the program to select the simulated trace from the plurality of candidate simulated traces based on a length of each candidate simulated trace.

11. An automated routing system, comprising:
a processor; and
a memory device, coupled to the processor, wherein the memory device stores a program and design information, the design information comprising a start point, an end point, a first direction, and a second direction;
wherein the processor is configured to execute the program to generate a simulated trace from the start point to the end point, and a starting segment of the simulated trace is connected to the start point and extends from the start point toward the first direction, and an ending segment of the simulated trace is connected to the end point and extends from the end point toward the second direction.

12. The automated routing system of claim 11, wherein the processor is configured to execute the program to establish a routing space using a plurality of voxels, and to constrain the start point, the end point, and the simulated trace to be within the routing space.

13. The automated routing system of claim 12, wherein the processor is configured to execute the program to record, in the memory device, voxels occupied by a structure within the routing space, and to cause the simulated trace to be immediately adjacent to the structure based on the voxels occupied by the structure within the routing space.

14. The automated routing system of claim 11, wherein the processor is configured to execute the program to generate the simulated trace according to a trace width.

15. The automated routing system of claim 14, wherein the processor is configured to execute the program to record, in the memory device, voxels occupied by at least one obstacle within a routing space, and, according to the trace width, to prevent voxels of the simulated trace from overlapping with the voxels occupied by the at least one obstacle within the routing space.

16. The automated routing system of claim 11, wherein the processor is configured to execute the program to record, in the memory device, a position occupied by at least one obstacle within a routing space, and to cause the simulated trace to route around the at least one obstacle.

17. The automated routing system of claim 16, wherein the
processor is configured to execute the program to generate a plurality of candidate simulated traces, wherein each candidate simulated trace routes around the at least one obstacle, a starting segment of each said candidate simulated trace is connected to the start point and extends from the start point toward the first direction, and an ending segment of each said candidate simulated trace is connected to the end point and extends from the end point toward the second direction; and
wherein the processor is configured to execute the program to select the simulated trace from the plurality of candidate simulated traces based on a turn count of each candidate simulated trace.

18. The automated routing system of claim 17, wherein the selected simulated trace is one of the plurality of candidate simulated traces having a fewest turn count.

19. The automated routing system of claim 11, wherein the processor is configured to execute the program to set at least one waypoint in a routing space, and to cause the simulated trace to pass through the at least one waypoint.

20. The automated routing system of claim 11, wherein the processor is configured to execute the program to generate a plurality of candidate simulated traces, wherein a starting segment of each candidate simulated trace is connected to the start point and extends from the start point toward the first direction, and an ending segment of each said candidate simulated trace is connected to the end point and extends from the end point toward the second direction; and
wherein the processor is configured to execute the program to select the simulated trace from the plurality of candidate simulated traces based on a length of each candidate simulated trace.
